(19) United States
(12) Patent Application Publication
(10) Pub. No.: US 2012/0098758 A1
(43) Pub. Date: Apr. 26, 2012

(54) Electronic program guide, mounting bracket and associated system

(75) Inventors: Michael Jefferson Tull, Anchorage, KY (US); Sandra Kay Tull, Anchorage, KY (US)

(73) Assignee: Fearless Designs, Inc. d/b/a The Audience Group

(21) Appl. No.: 12/926,037

(22) Filed: Oct. 22, 2010

(51) Int. Cl. G06F 3/041; H05K 7/14

(52) U.S. Cl. 345/173; 248/205.1

(57) ABSTRACT

A hand held battery powered interactive e-reader-type module facilitates delivery of program information electronically directly to a person sitting in a theater or stadium seat. It includes a receiver and transmitter to allow receipt of program information and transmission of requests such as the purchase of tickets, enhanced content for upcoming shows, contacting program advertisers and content feedback via messaging, etc. The module is releasably mounted on a bracket mounted on the back of a seat. A holster is mounted on the bracket and has an upper opening that allows the module to be slid into the holster from above and to be retained in position.

### BACKGROUND OF THE INVENTION

The present invention relates to an electronic program guide, mounting bracket and associated system. As patrons of the arts know, when attending an event such as an opera, play, musical, concert or other events held at theater, playhouse, arena, stadium, etc., each attendee receives a printed paper program. These programs typically have dozens of pages and some even exceed 100 pages in length. Typically, these programs are used once and thrown away. When one thinks of all of the events that occur throughout the United States on any given day and the amount of paper, chemicals and petroleum products that are employed in printing these programs, the amount of paper used is simply astronomical.

As the human population increases and the need for space for housing, recreation, athletic pursuits, arts and civic activities increases correspondingly, and as the human need for information that is printed is maintained at a high level, all of this operates to the detriment of our forests. Tree cover decreases acre by acre as time goes by. One often reads about the diminution of our forests and tree cover mainly due to human activity such as development of land and manufacture of paper products.

It would advance the cause of preservation of the earth's valuable and scarce resources, particularly resources used to manufacture paper products, if means were employed that would reduce the dependence upon printed materials. It is with this thought in mind that the present invention was developed.

### SUMMARY OF THE INVENTION

The present invention relates to an electronic program guide, mounting bracket and associated system for use in a performance venue such as a theater or stadium. The present invention includes the following interrelated objects, aspects and features:

(1) The heart of the present invention consists of a hand held, interactive e-reader-type module that facilitates delivery of program information electronically directly to a person sitting in a theater or stadium seat. The module is battery powered with a rechargeable battery and includes a receiver and transmitter to allow receipt of program information and transmission of requests such as the purchase of tickets, enhanced content for upcoming shows, contacting program advertisers and content feedback via messaging, etc.

(2) The module includes features allowing display of program material and paging forward and backward through the manipulation of buttons displayed on its front surface or a touch function of the software, or scrolling using thumbnail page icons displayed on its front surface and touching the desired page. Provision is made to allow the user to enlarge program material or reduce it in size, to access expanded program content and interact online with program advertisers and producers. Provision is made to allow the theater operator to remotely turn the screen display on and off as well as activate and disable module function. Thus, the display may be turned on when the theater lights are up and off when the theater lights are down. The module also may include a security anti-theft chip.

(3) In the preferred embodiment, the module is releasably mounted on a bracket that is mounted on the back of the seat in front of the seat where the theater patron is to sit. The bracket includes side rearwardly extending arms and a lower detent. A holster is mounted on the bracket and has an upper opening that allows the module to be slid into the holster from above and to be retained in position.

(4) The system associated with the present invention includes a plurality of modules, the brackets mounted on the seats as well as an associated recharging system in which the modules can be plugged between programs to allow the rechargeable batteries of the modules to be recharged so that they are at full power when they are distributed to theater patrons.

(5) The system may include the ability of the theater operator to disable the web functions of all the modules in a theater.

(6) The present invention is able to expand the information available to patrons reading programs in theaters by wirelessly connecting them to information sources outside the theater. By introducing a reusable and more responsive vehicle for communication between the patron and producer, advertiser and theater manager, for every performance, the present invention enhances the user's enjoyment while diminishing the negative impact of paper programs on the environment.

(7) Through use of the present invention, new information may be electronically edited, expanded and reloaded, and the information may be deleted as well, without taking the device off its premises.

(8) This provides a new level of immediacy not available with traditional paper programs. Navigation of the program content, both manually and numerically, mimics traditional navigation through a paper program but with greater speed and accuracy. Thumbnail images that have been downloaded to the theater hub are supplied to the module wirelessly and appear in chronological order on the bottom of the module in a row of images. Touching each thumbnail causes its display on the full screen at 100% the size of a traditional paper program page.

(9) Specific sites are encoded to limit accessibility to just those holding a module. A theater hub is the control source for activating and deactivating module functions as well as for changing program materials. The theater hub also serves as the gatekeeper to the worldwide web. All outside data is delivered to the theater hub from an outside source such as the service known by the Service Mark “AUDIENCE.” There, a staff of designers and technicians input and assemble text and graphics while also adding restrictive codes to limit recipients to those holding modules as well as to limit the ability of a module holder to only use the module and its wireless Internet access functions to access sites, data, program materials, advertiser websites, etc. as proscribed by the encoding.

(10) The reusable modules are both reprogrammable and rechargeable, thereby providing a continuous and paper free source of information. Portable recharging carts function to both store the modules and recharge them while allowing the modules to be easily transported.

As such, it is a first object of the present invention to provide an electronic program guide, mounting bracket and associated system.

It is a further object of the present invention to provide such an invention in which a plurality of modules are maintained with their batteries in a charged state so that each module is effectively usable throughout the time of a performance.

It is a still further object of the present invention to provide such an invention in which the module allows display of program material, advertising material as well as individual or group messages.

It is a still further object of the present invention to provide such a system in which the modules are releasably mountable on brackets installed on the backs of seats in a theater.

It is a still further object of the present invention to provide such a system in which a recharging station is provided at which modules may be plugged in to be connected to a source of electricity where the rechargeable batteries thereof can be recharged.

These and other objects, aspects and features of the present invention will be better understood from the following detailed description of the preferred embodiment when read in conjunction with the appended drawing figures.

### BRIEF DESCRIPTION OF THE DRAWINGS

FIG. 1 shows a front view of the inventive module.

FIG. 2 shows a front view including the user-operative screen display functions.

FIG. 3 shows a side view of the inventive module.

FIG. 4 shows an enlarged front view of screen-displayed thumbnail representations of the program pages.

FIG. 5 shows a front schematic representation of screen-displayed operating buttons of the module explaining the manner of operation thereof.

FIG. 6 shows a front view of a bracket designed to hold the inventive module.

FIG. 7 shows a cross-sectional view along the line 7-7 of FIG. 6.

FIG. 8 shows a cross-sectional view along the line 8-8 of FIG. 6.

FIG. 9 shows a front view of a pad to be mounted to the inventive bracket.

FIG. 10 shows a side view of the pad of FIG. 9.

FIG. 11 shows a front cross-sectional view of a holster designed to be mounted to the bracket and receive the module.

FIG. 12 shows a cross-sectional view along the line 12-12 of FIG. 11.

FIG. 13 shows a cross-sectional view along the line 13-13 of FIG. 12.

FIG. 14 shows a top view of the bracket, holster and pad as mounted together with respect to a chair with a curved back.

FIG. 15 shows an exploded perspective view of the structure of FIG. 14.

FIG. 16 shows a view similar to that of FIG. 15, but used with a chair having a flat back.

FIG. 17 shows an exploded perspective view of the structure of FIG. 16.

FIG. 18 shows the internal electrical circuitry of the inventive module.

FIG. 19 shows a front view of the inventive module with information displayed thereon.

FIG. 20 shows a schematic representation of the module including how it communicates exteriorly.

FIG. 21 shows a front perspective view of a recharging station.

FIG. 22 shows a side view of the recharging station of FIG. 21.

FIG. 23 shows a rear view of the recharging station of FIGS. 21 and 22.

### SPECIFIC DESCRIPTION OF THE PREFERRED EMBODIMENTS

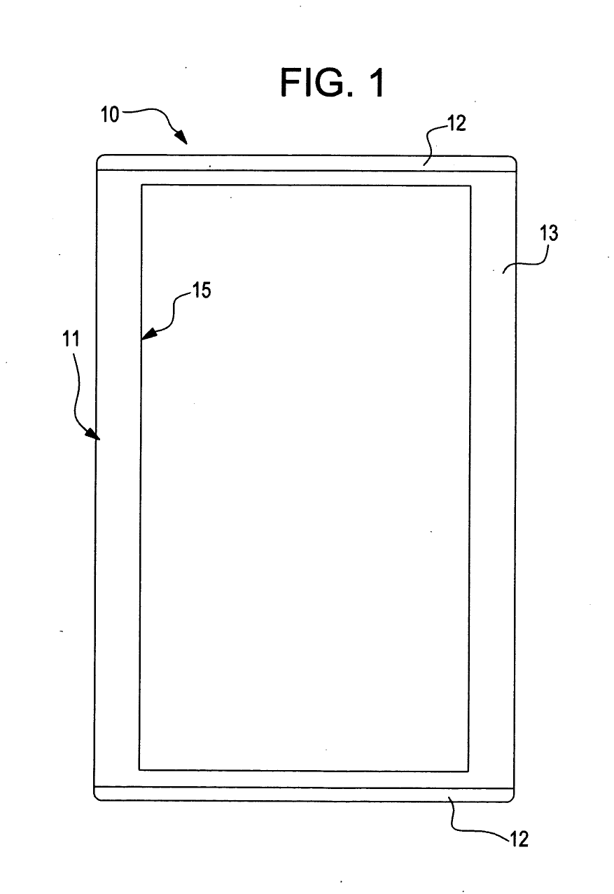

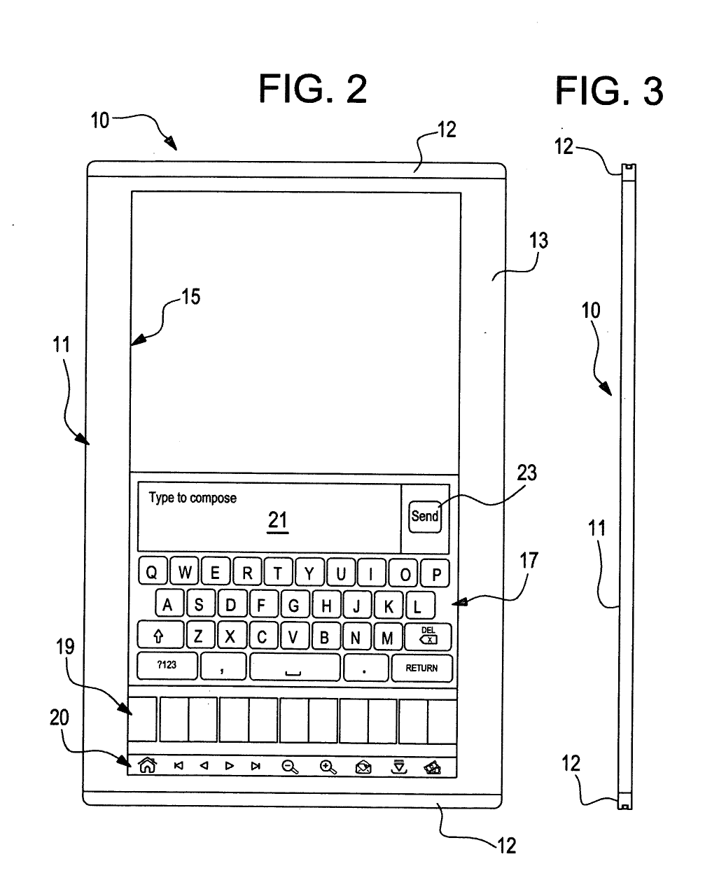

Reference is first made to FIGS. 1-5 so that a description of the inventive module 10 may be had. With reference first to FIG. 1, the module 10 includes a housing 11 having a front face 13 on which is located a display 15. FIG. 2 shows features of the interactive screen display including a keyboard 17 as well as thumbnail representations of the program pages and corresponding page number in a row designated by the reference numeral 19. Below 19, a row of buttons 20 is provided with an indicia on each button indicating the result of depressing the button. FIG. 3 shows that the housing 11 of the module 10 is extremely thin in keeping with the purposes of the present invention. The strip 12 facilitates recharging the module 10 by surface-to-surface contact with a recharging station.

With reference back to FIG. 2, the keyboard 17 is a standard “QWERTY” style keyboard allowing the user to type a desired input. The small display 21 displays what is being typed until the SEND button 23 is depressed.

The display 15 is intended to display program material such as a program from a performance that is being watched by the user as well as advertising of sponsors of the program as well as other possible messages. For example, the display 15 may also display special notices from the theater as to their policies concerning such things as smoking, eating, noise, etc. The display 15 may also display information such as changes in the cast of a production, and other messages.

The inventive module 10 includes a built-in transmitter-receiver. This facilitates communication with both the theater operator and the worldwide web (Internet) by a user of the module 10. Messages from the theater operator such as theater policy, emergencies, etc. are received by each module for viewing by its user. Users may access additional program content from show producers as well as enter advertiser's web sites.

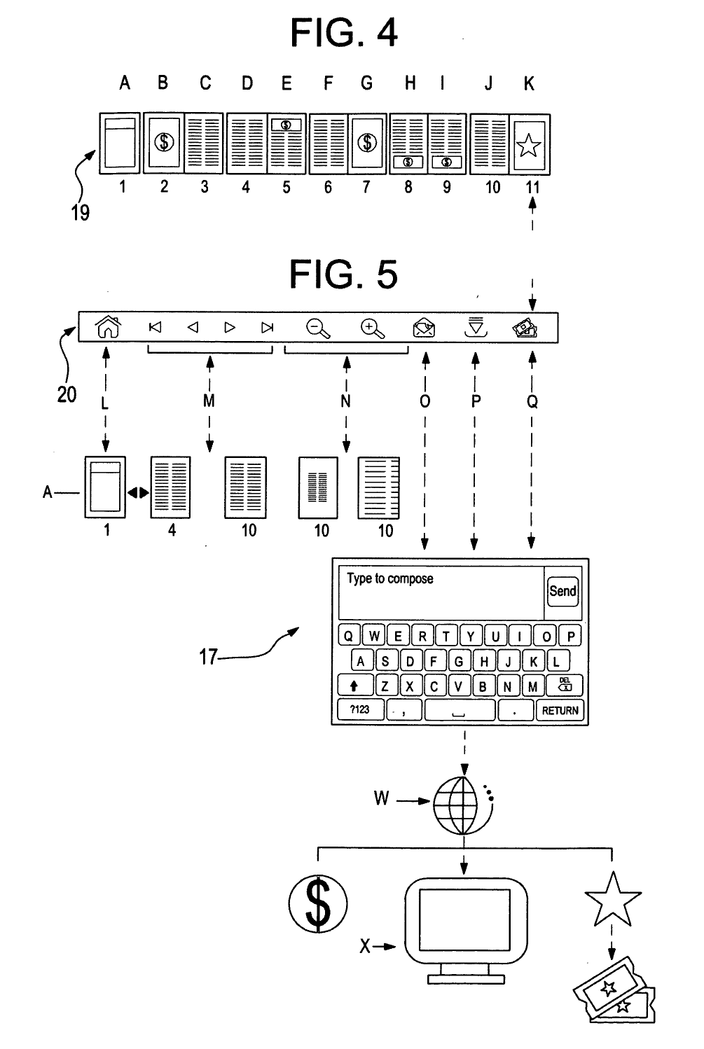

The program page thumbnail buttons in the row 19 are shown in more detail in FIGS. 4 and 5. FIG. 4 shows more detail illustrating that there is a unique page thumbnail for each page of the program. Thus, for example, A with the corresponding numeral 1 below represents the program cover (page 1). B and G represent advertiser pages. C, D, F and J represent program content pages in the playbill. E, H and I represent pages containing both advertising and program content. K represents a page containing information or advertising by the theater, ticket distributor or performance group.

The row of indicia 20 in FIG. 5 facilitates the user's ability to operate software functions of module 10. The button L returns the user to page 1 of the program. The buttom M, when depressed, facilitates advancing or going back concerning pages on a playbill. The button N in row 20, when depressed, facilitates enlarging the text or reducing it as the case may be. When the button O is depressed, the user can communicate via the keypad 17 with the theater, show producers or advertisers. Button P allows the user to access a remote location via keypad 17 for the purpose of transferring the program page content. The button Q facilitates purchase of tickets for future shows. The globe W signifies connecting the module 10 to the worldwide web (Internet) via the theater hub X.

As explained above, the purpose for the module 10 is to replace paper programs at performances conducted at theaters, playhouses, etc., and to also enhance the versatility of the experience by allowing the user to contact the web sites of program advertisers as well as to search for information about artists and any other information allowed by the programmer.

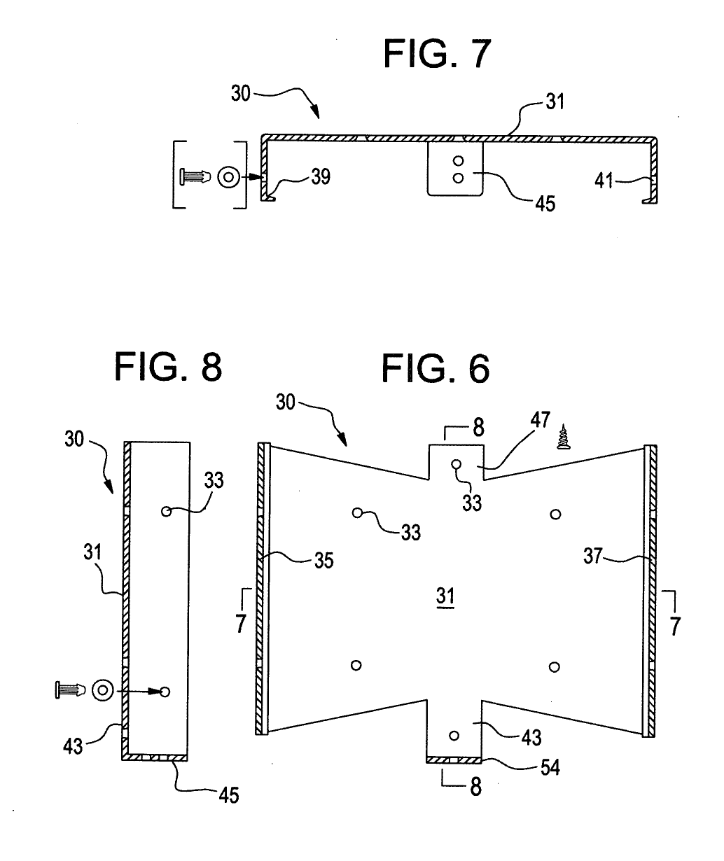

With reference now to FIGS. 6-19, the manner of removable placement of the module 10 for use by a theater goer will now be explained in detail.

With reference first to FIGS. 6-8, a bracket system includes a bracket generally designated by the reference numeral 30 and including a flat rear surface 31 having a plurality of holes 33 therein as well as side walls 35, 37 extending outwardly from the rear wall 31, and with the side walls 35 and 37 terminating in inwardly directed short walls 39 and 41, respectively. Depending downwardly from the wall 31 is a tang 43 which terminates in a forward facing wall 45. Also, a second tang 47 extends upwardly from the wall 31 and includes an additional hole 33. The holes 33 receive fasteners that allow the bracket 30 to be mounted on the rear face 2 of a theater seat 1. This is shown with particular reference to FIGS. 15 and 17. In FIG. 15, what is depicted is a theater seat 1 with an arcuate curvature for the seat back 2. When this occurs, as will be described in greater detail hereinafter, the bracket 30 which is flexible is correspondingly curved. FIG. 17 shows a seat 1′ in which the seat back 2′ is flat. In that situation, the bracket 30 is correspondingly flat.

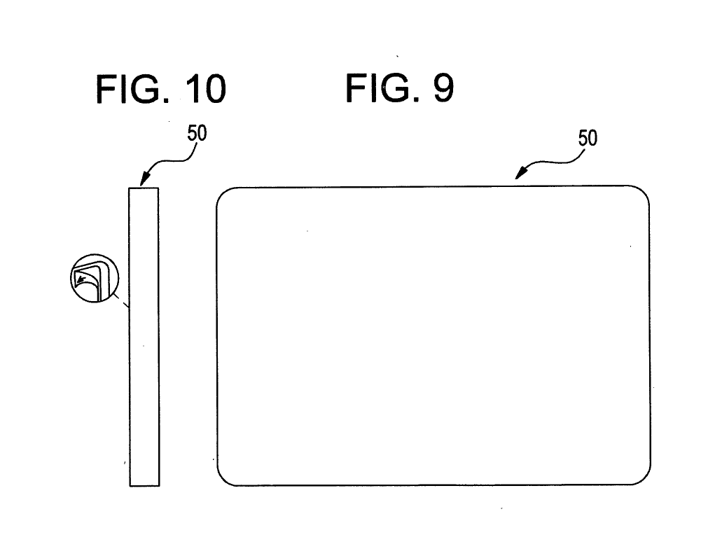

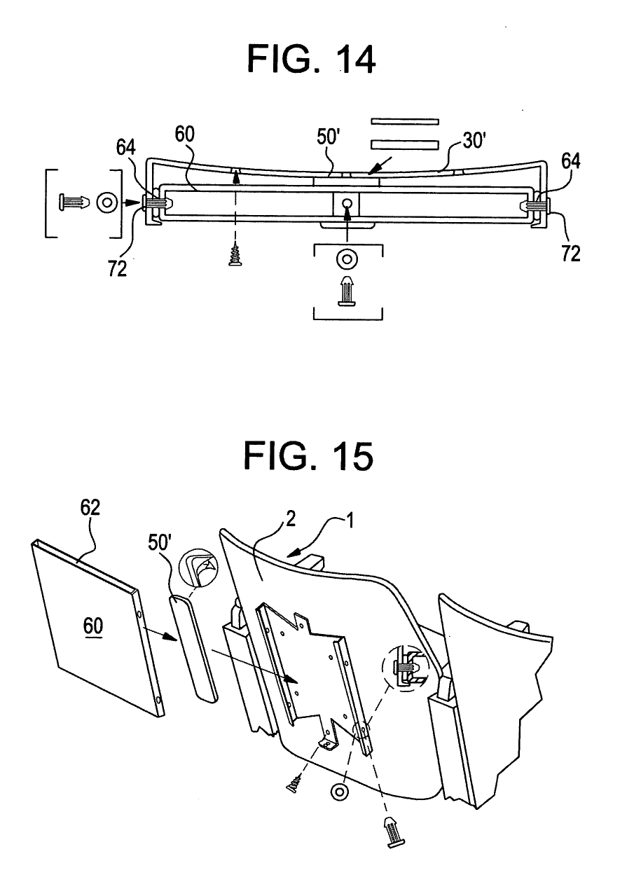

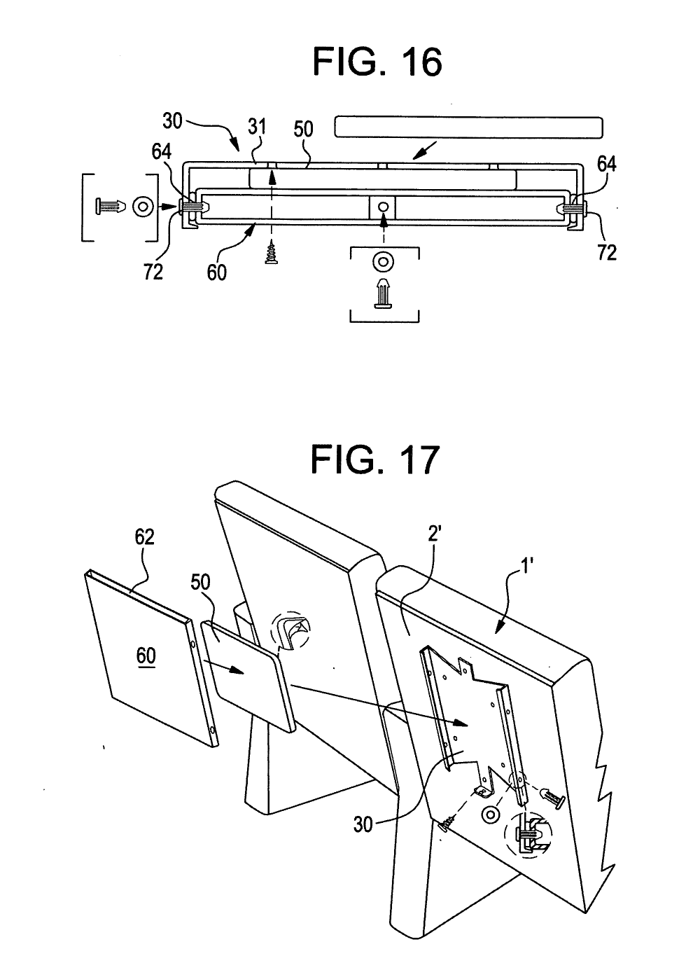

With reference now to FIGS. 9-10, a resilient pad 50 is shown in its front view (FIG. 9) and its side view (FIG. 10). The pad shown in FIGS. 9 and 10 corresponds to that which is also shown in FIGS. 16 and 17. The width of the pad 50 is equal to a majority of the width of the bracket 30 because the seat back 2′ is flat. In the circumstance shown in FIGS. 14 and 15, in which the seat back 2 is curved, the pad 50′ shown in FIGS. 14 and 15 is instead made extremely narrow so that it can provide sufficient padding as will be described in greater detail hereinafter while accounting for the curvature of the seat back 2.

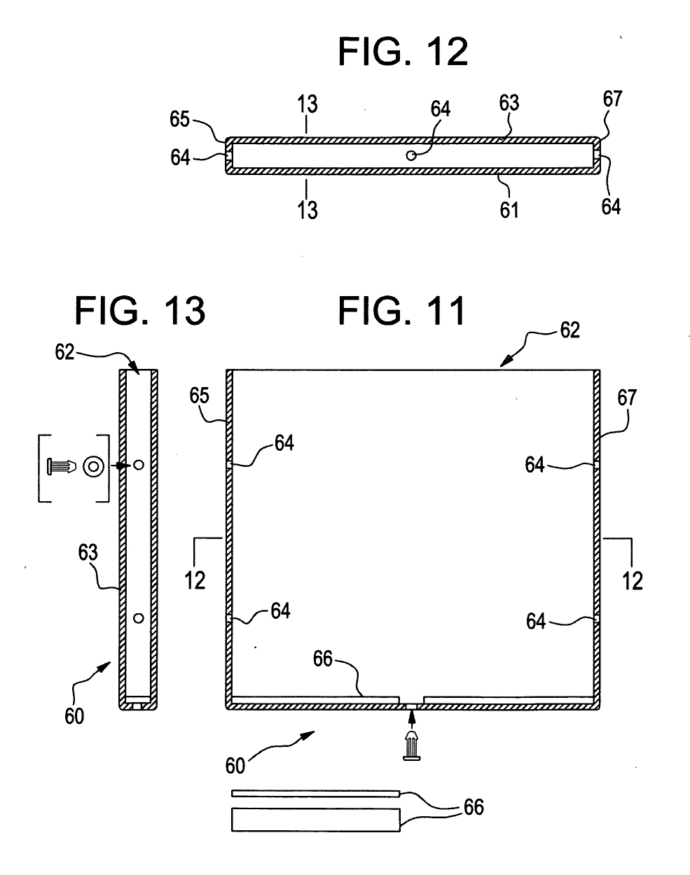

With reference now to FIGS. 11-17, a holster is generally designated by the reference numeral 60 and with particular reference to FIGS. 11-13, includes a front wall 61, a rear wall 63, and side walls 65 and 67. As seen in FIGS. 11 and 13, the holster 60 has an upwardly directed opening 62 that allows the module 10 to be placed therein. A rubber pad 66 cushions the module as it is inserted into the holster. A series of holes 64 are provided in the holster 60 to facilitate mounting it within the bracket as best seen with reference to FIGS. 14-17.

With reference to FIGS. 14 and 15, the bracket is designated by the reference numeral 30′ since it has an arcuate configuration to match the curvature of the arcuate seat back 2 and to distinguish it from the bracket 30 shown in FIGS. 16-17, in which the rear wall 31 is shown as flat. The bracket 30 has mounted thereto the narrow pad 50′ (FIGS. 14 and 15) and the holster 60 is mounted to the bracket 30′ through the use of fasteners 72 extending through openings 64 in the walls of the holster 60 as explained above. The module 10 may easily be slipped into the holster 60 through the opening 62 as explained above so that it may be stored there when it is not in use.

With reference to FIGS. 16-17, the bracket 30 has a flat rear wall 31 corresponding to the flat rear wall 2′ of the theater seat 1′ as shown in FIG. 17. Thus, the wider pad 50 is placed on the rearwardly facing surface of the wall 31 and the holster 60 is mounted thereto using the fasteners 72 extending through the openings 64 in the holster 60 as explained above with reference to FIGS. 14-15.

Thus, it should be understood that two configurations of the bracket 30, 30′ and pad 50, 50′ facilitate the mounting of the holster 60 on any seat configuration with the holster 60 being able to receive the module 10 for storage when the user wishes to rest the module 10 and not have to hold it.

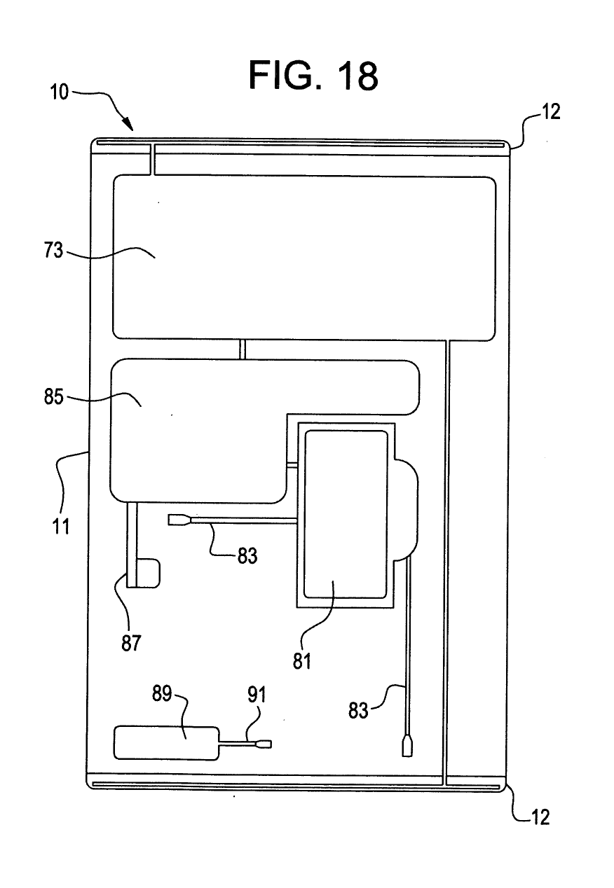

FIG. 18 shows the electrical circuitry of the present invention schematically. The strip 12 is connected to the battery 73. The WIFI transmitter/receiver 81 is connected to WIFI antenna 83 and controlled by logic board 85. The logic board 85 is connected to the display data cable 87; the logic board operates the module 10 including the display 15. An anti-theft transmitter 89 with antenna 91 is mounted in the module 10 to protect against its theft. When the module 10 is removed from the theater area, it sends a signal to the theater operator.

The display includes a special “touch screen” capability. When an advertisement is displayed, touching the display activates the WIFI transmitter/receiver 81 to connect the device 10 to the web site of the advertiser who provided the advertisement.

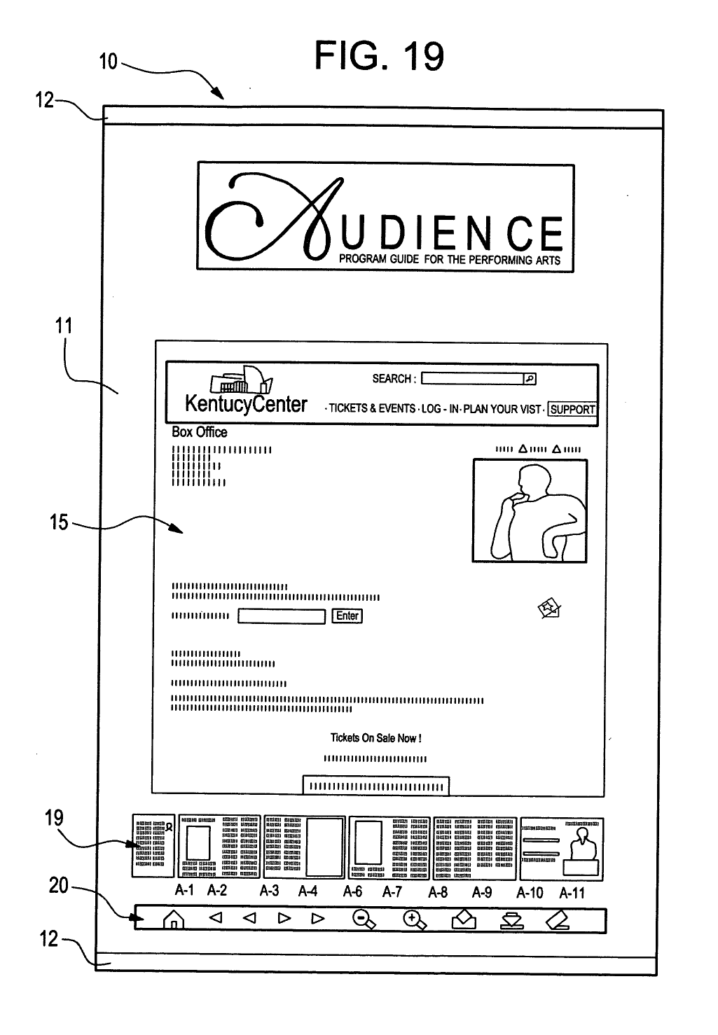

FIG. 19 shows an example of subject matter displayed on said display 15.

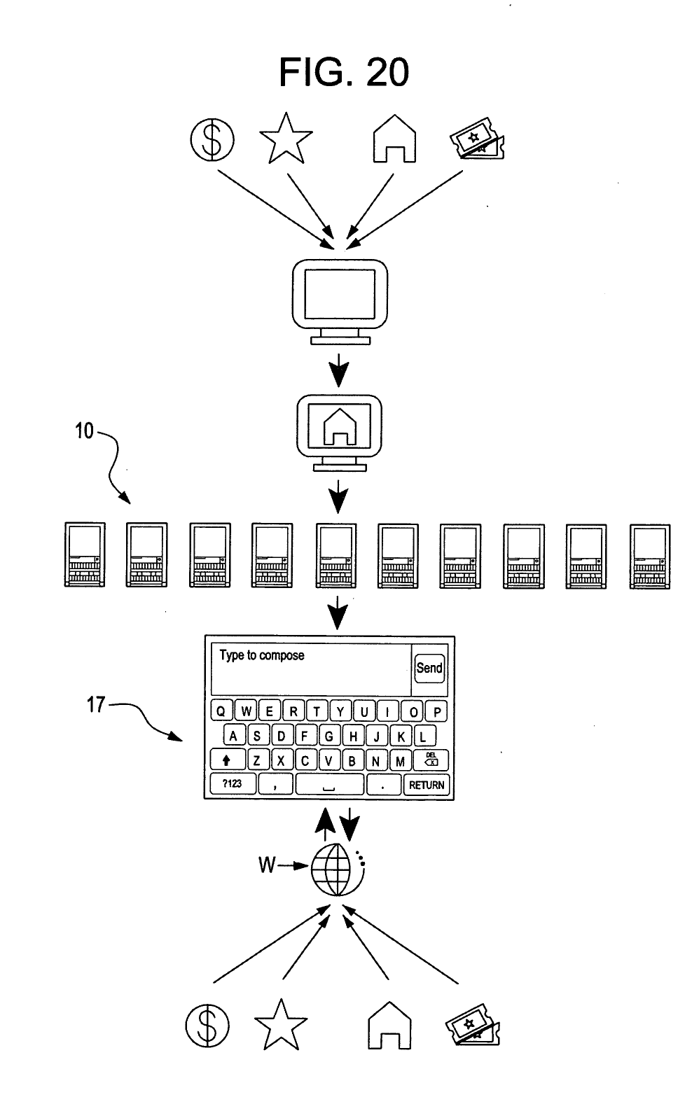

FIG. 20 shows an example of the module 10 in which information is displayed on the display 15 and the other features are clearly shown including information displayed on the page thumbnails in the row 19. Interactive tools are displayed in the row 20 at the bottom of the module 10.

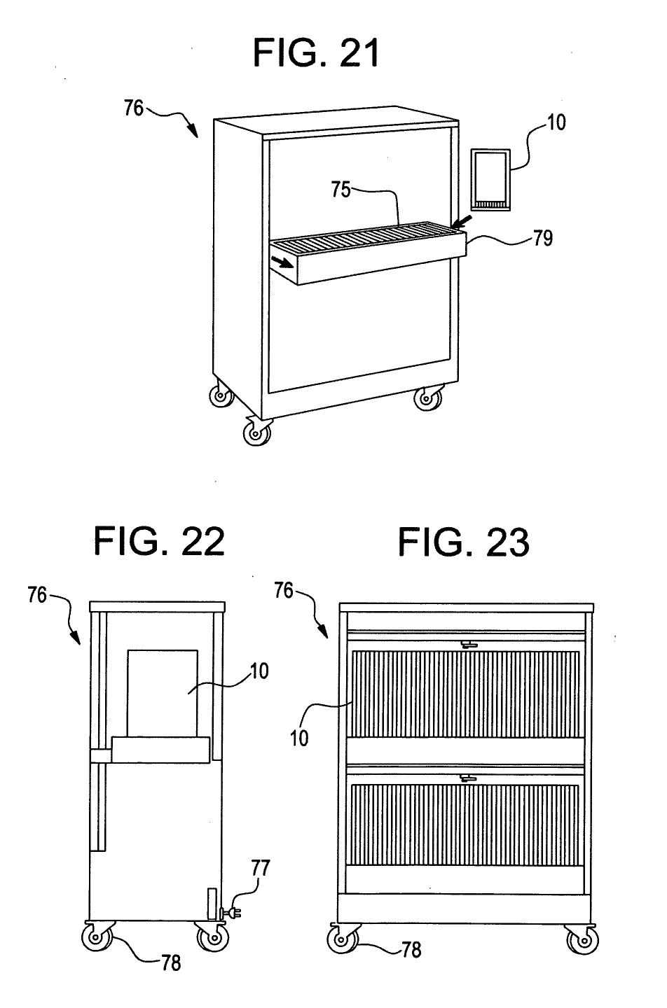

In order to best facilitate use of the inventive system, if desired, with reference to FIGS. 21-23, a theater operator may have a recharging station 76 at which any of the modules 10 corresponding to the number of seats in the theater may be plugged in so that they may be recharged. What is contemplated is a large cart 76 (as shown in the Figures) having a plurality of receptacles 75, each of which is designed to receive the strip 12 of a module 10 so that the battery of the module 10 may be connected with a source of electricity (not shown) via an electrical conductor and plug 77 to charge the battery up to its maximum level of charge. The cart may be on wheels 78 so that it can be rolled from a secure location where it is connected to a source of electricity to perform the charging function, and may be rolled from that location when it is unplugged to a location where theater patrons may each be given a module 10.

In accordance with the teachings of the present invention, through use of the inventive module 10 and the associated brackets 30, 30′, and the charging station 76, a self-contained, reusable means for providing theater patrons information concerning a production that is occurring at the theater as well as enabling them to communicate with the Internet, receive messages, download program content to an off-site location, and order tickets for subsequent productions, is provided in a highly effective manner.

As such, an invention has been disclosed in terms of preferred embodiments thereof which fulfill each and every one of the objects of the invention as set forth hereinabove, and provide a new and useful electronic program guide, mounting bracket and associated system of great novelty and utility.

Of course, various changes, modifications and alterations in the teachings of the present invention may be contemplated by those skilled in the art without departing from the intended spirit and scope thereof.

As such, it is intended that the present invention only be limited by the terms of the appended claims.

1. An electronic program guide for use in a performance venue, comprising:
a) a housing containing a battery;
b) said housing having a display, a keyboard, and a plurality of software function operating keys;
c) said housing containing a logic board powered by said battery and operating said guide and a WIFI transmitter/receiver including an antenna;
d) said WIFI transmitter/receiver facilitating communication with a theater hub to receive data to be displayed on said display in the form of an electronic program related to a performance to be performed in said performance venue.

2. The electronic program guide of claim 1, wherein said battery is rechargeable.

3. The electronic program guide of claim 2, wherein said battery is connected to an electrically conductive connector mounted on an outside surface of said housing.

4. The electronic program guide of claim 3, wherein said connector comprises an elongated strip.

5. The electronic program guide of claim 1, wherein said WIFI transmitter/receiver facilitates communication between said guide and Internet web sites.

6. The electronic program guide of claim 5, wherein said web sites are limited to those of sponsors of said performance being performed in said performance venue.

7. The electronic program guide of claim 1, wherein said housing further includes a plurality of program page thumbnail buttons, each of which corresponds to a page of said electronic program, said buttons being depressed to cause respective ones of said pages to be displayed on said display.

8. The electronic program guide of claim 7, wherein said display may display advertising, and when said advertising is touched by a user, said guide is connected to a web page of an advertiser who has provided said advertising.

9. The electronic program guide of claim 8, wherein further buttons are provided which, when depressed, facilitate enlargement or reduction of page size as displayed on said display.

10. The electronic program guide of claim 1, further including a temporary display that temporarily displays data inputted by said keyboard until sent to said display.

11. The electronic program guide of claim 1, further including an anti-theft transmitter actuated when said guide is removed from a particular area.

12. A bracket system for releasably holding an electronic module, comprising:
a) a bracket having a forward surface attachable to a rear surface of a seat;
b) said bracket including side walls forming a channel and a bottom rearwardly extending tang; and
c) a holster releasably received in said channel, said holster having an inner chamber with an upwardly facing opening and a lower surface engaging said tang.

13. The bracket system of claim 12, wherein said tang includes a rearward facing surface on which said lower surface of said holster rests.

14. The bracket system of claim 12, further including a resilient pad interposed between said bracket and holster.

15. The bracket system of claim 12, wherein said rear surface of said seat is flat.

16. The bracket system of claim 12, wherein said rear surface of said seat is curved.

17. The bracket system of claim 12, wherein said holster is fastened to said bracket.

18. The bracket system of claim 12, further including an electronic module removably received in said inner chamber of said holster, said electronic module including:
a) a housing containing a battery;
b) said housing having a display, a keyboard, and a plurality of software function operating keys;
c) said housing containing a logic board powered by said battery and operating said guide and a WIFI transmitter/receiver including an antenna;
d) said WIFI transmitter/receiver facilitating communication with a theater hub to receive data to be displayed on said display in the form of an electronic program related to a performance to be performed in said performance venue.

19. The bracket system of claim 18, wherein said housing further includes a plurality of program page thumbnail buttons, each of which corresponds to a page of said electronic program, said buttons being depressed to cause respective ones of said pages to be displayed on said display.

20. The bracket system of claim 19, wherein additional buttons are provided which, when depressed, facilitate display of advertising.
